(19) United States
(12) Patent Application Publication
(10) Pub. No.: US 2026/0351880 A1
(43) Pub. Date: Nov. 5, 2026

(54) CHIP-TO-PANEL CABLE ASSEMBLY AND CIRCUIT BOARD ASSEMBLY

(71) Applicant: Micas Networks Inc., SAN JOSE, CA (US)

(72) Inventor: Zaiyi LIAO, SAN JOSE, CA (US)

(73) Assignee: Micas Networks Inc., SAN JOSE, CA (US)

(21) Appl. No.: 19/706,721

(22) Filed: Jun. 12, 2026

Related U.S. Application Data
(63) Continuation of application No. PCT/CN2026/076805, filed on Feb. 3, 2026.

(30) Foreign Application Priority Data
Mar. 6, 2025 (CN) 202520384785.0

(51) Int. Cl. H01R 12/79

(52) U.S. Cl. CPC H01R 12/79

(57) ABSTRACT

This application relates to a chip-to-panel cable assembly and a circuit board assembly. The chip-to-panel cable assembly includes at least a first connection unit and a second connection unit; where the first connection unit includes a first flexible circuit board, and a first connector and a second connector that are disposed on the first flexible circuit board; where the first connector is used to be electrically connected to an external module, and the second connector is used to be electrically connected to a chip connector; and the second connection unit includes a second flexible circuit board, and a third connector and a fourth connector that are disposed on the second flexible circuit board; where the third connector is used to be electrically connected to an external module, and the fourth connector is used to be electrically connected to a chip connector; where at least a partial region of the first flexible circuit board close to the second connector and at least a partial region of the second flexible circuit board close to the fourth connector are stacked with each other.

### CROSS-REFERENCE TO RELATED APPLICATIONS

This application is a continuation application of International Application No. PCT/CN2026/076805, which claims priority to Chinese Patent Application No. 202520384785.0, filed on Mar. 6, 2025, with the China Patent Office, and entitled “CHIP-TO-PANEL CABLE ASSEMBLY AND CIRCUIT BOARD ASSEMBLY”, which are incorporated herein by reference in their entireties.

### TECHNICAL FIELD

This application relates to the field of communication technologies, and particularly to a chip-to-panel cable assembly and a circuit board assembly.

### BACKGROUND

A physical channel of chip-to-module (C2M) serves as the most important physical layer interconnection of a communication device. A topology structure mainly includes connection between a main control chip and an input/output (I/O) connector. To meet data communication requirements, the C2M channel shall satisfy channel loss requirements, which are generally implemented through high-speed copper cable connections.

### SUMMARY

Embodiments of this application provide a chip-to-panel cable assembly, including at least a first connection unit and a second connection unit; where
the first connection unit includes a first flexible circuit board, and a first connector and a second connector that are disposed on the first flexible circuit board; where the first connector is used to be electrically connected to an external module, and the second connector is used to be electrically connected to a chip connector; and
the second connection unit includes a second flexible circuit board, and a third connector and a fourth connector that are disposed on the second flexible circuit board; where the third connector is used to be electrically connected to an external module, and the fourth connector is used to be electrically connected to a chip connector; where
at least a partial region of the first flexible circuit board close to the second connector and at least a partial region of the second flexible circuit board close to the fourth connector are stacked with each other.

In one embodiment, the first flexible circuit board includes a first portion and a second portion that are connected to each other and arranged at an angle; the first connector is disposed on the first portion, and the second connector is disposed on the second portion;
the second flexible circuit board includes a third portion and a fourth portion that are connected to each other and arranged at an angle; the third connector is disposed on the third portion, and the fourth connector is disposed on the fourth portion; and
the second portion and the fourth portion are stacked with each other to allow the second connector and the fourth connector to be stacked with each other.

In one embodiment, the first portion includes a first diverging region, and the first connector is disposed on the first diverging region;
the second portion includes a second diverging region, and the third connector is disposed on the second diverging region; where
projections of the first diverging region and the second diverging region on a first reference plane do not overlap, and the first reference plane is perpendicular to a stacking direction of the second portion and the fourth portion.

In one embodiment, the first portion is bent towards a first side of the cable assembly relative to the second portion, the third portion is bent towards a second side of the cable assembly relative to the fourth portion, the first side is opposite from the second side with respect to a second reference plane, and the second reference plane is perpendicular to the first reference plane.

In one embodiment, the first portion is bent towards a first side of the cable assembly relative to the second portion, and the third portion is also bent towards the first side relative to the fourth portion; and
the first portion and the third portion are stacked with each other to allow the first connector and the third connector to be stacked with each other.

In one embodiment, an area of a stacked portion of the second portion and the fourth portion is greater than 80% of an area of the second portion and/or greater than 80% of an area of the fourth portion.

In one embodiment, the first connector and the third connector are fixed to optical cages via first positioning members; and/or
the second connector and the fourth connector are fixed with each other via a second positioning member; and/or
the first flexible circuit board and the second flexible circuit board are fixed with each other via a third positioning member.

In one embodiment, the second connector and the fourth connector are fixed with each other via a second positioning member, and the second connector and the fourth connector have a spacing along a thickness direction of the second portion and the fourth portion; and
the second portion and the fourth portion are configured as elongated strip-shaped members, and the second portion and the fourth portion have different lengths.

In one embodiment, an insertion direction of the second connector and the fourth connector relative to the chip connector is along an extension direction of the first flexible circuit board in a horizontally orientated state; or
an insertion direction of the second connector and the fourth connector relative to the chip connector is perpendicular to an extension direction of the first flexible circuit board in a horizontally orientated state.

Embodiments of this application further provide a circuit board assembly, including: a first circuit board, a second circuit board, an optical cage that are arranged spaced apart from each other in a preset direction, and one or more of the above-mentioned cable assemblies; where
the first connector of the first connection unit and the third connector of the second connection unit are disposed on the optical cage, and the optical cage is disposed on the first circuit board; and
the second circuit board is provided with a chip connector, and the second connector and the fourth connector are connected to the chip connector.

In one embodiment, a quantity of the one or more cable assemblies is two, and the two cable assemblies are stacked with each other along a thickness direction of the first circuit board; where
the second connector and the fourth connector of one of the cable assemblies and the second connector and the fourth connector of the other one of the cable assemblies are fixed relative to each other by a second positioning member.

Beneficial effects of the foregoing chip-to-panel cable assembly and circuit board assembly are as follows:

The first connection unit includes a first flexible circuit board, and a first connector and a second connector that are disposed on the first flexible circuit board. The first connector is used to be electrically connected to an external module, and the second connector is used to be electrically connected to a chip connector, such that a partial electrical connection between the external module and the chip connector is realized via the first connector, the first flexible circuit board, and the second connector. Furthermore, the second connection unit includes a second flexible circuit board, and a third connector and a fourth connector that are disposed on the second flexible circuit board. The third connector is used to be electrically connected to an external module, and the fourth connector is used to be electrically connected to a chip connector, such that an electrical connection between the external module and the chip connector is also further realized via the third connector, the second flexible circuit board, and the fourth connector. Compared with copper cable connections in the related art, the occupied space is greatly reduced, and the structure can adapt to scenarios requiring high density and massive interconnections.

At least a partial region of the first flexible circuit board close to the second connector and at least a partial region of the second flexible circuit board close to the fourth connector are stacked with each other. The first flexible circuit board and the second flexible circuit board are thin plate-like structures. Therefore, arranging at least a partial region of the first flexible circuit board and at least a partial region of the second flexible circuit board to be stacked with each other can greatly reduce the overall space occupied by the first flexible circuit board and the second flexible circuit board, as compared with the side-by-side arrangement of the first flexible circuit board and the second flexible circuit board. This structure releases heat dissipation space within the electronic device, thereby improving the heat dissipation performance of heating elements in the electronic device.

On the other hand, copper cable connection is no longer required, and relatively complex assembly processes are omitted accordingly. During connection, it is only necessary to perform plugging connection of the first connector and the third connector with a target external module, and perform plugging connection of the second connector and the fourth connector with a chip connector on a target circuit board. This is suitable for high-density and massive interconnection scenarios, and features simple assembly and small occupied space in a chip-to-panel cable assembly and the circuit board assembly.

### BRIEF DESCRIPTION OF DRAWINGS

FIG. 1 is a schematic structural diagram of a chip-to-panel cable assembly according to an embodiment of this application;

FIG. 2 is a side view of a chip-to-panel cable assembly according to an embodiment of this application;

FIG. 3 is a schematic diagram of another structure of a chip-to-panel cable assembly according to an embodiment of this application;

FIG. 4 is a schematic structural diagram of a circuit board assembly according to an embodiment of this application; and

FIG. 5 is a schematic structural diagram of another structure of a circuit board assembly according to an embodiment of this application.

### DESCRIPTION OF REFERENCE SIGNS IN THE DRAWINGS

100: cable assembly;
10: first connection unit;
20: first flexible circuit board; 21: first portion; 22: second portion;
30: first connector;
41: first positioning member; 42: second positioning member;
50: second connector;
60: second connection unit;
70: second flexible circuit board; 71: third portion; 72: fourth portion;
80: third connector; 90: fourth connector;
200: circuit board assembly;
210: first circuit board; 220: second circuit board; 230: chip connector; 240: optical cage;
C1: first diverging region; C2: second diverging region; S1: first side; and S2: second side.

### DESCRIPTION OF EMBODIMENTS

In order to make the above-mentioned objects, features, and advantages of this application more obvious and understandable, the specific embodiments of this application are described in detail below with reference to the accompanying drawings. Many specific details are set forth in the following description to provide a thorough understanding of this application. However, this application may be implemented in many other ways different from those described herein, and those skilled in the art may make similar improvements without departing from the spirit of this application. Therefore, this application is not limited by the specific embodiments disclosed below.

In the description of this application, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential”, and the like indicating orientation or positional relationships are based on the orientation or positional relationships shown in the drawings, and are only for the convenience of describing this application and simplifying the description, and do not indicate or imply that the device or element referred to must have a specific orientation, be constructed and operated in a specific orientation, and therefore cannot be understood as a limitation on this application.

Furthermore, the terms “first” and “second” are used for descriptive purposes only and should not be understood as indicating or implying relative importance or implicitly indicating the quantity of indicated technical features. Thus, features defined by “first” and “second” may explicitly or implicitly include at least one such feature. In the description of this application, the meaning of “multiple” is at least two, for example, two or three, unless otherwise explicitly and specifically defined.

In this application, unless otherwise explicitly specified and defined, terms such as “mounting”, “connection”, “coupling”, and “fixation” should be broadly understood. For example, the connection may be fixed connection, or detachable connection, or integrated connection; may be mechanical connection, or electrical connection; may be directly connection, or indirectly connection through an intermediate medium; or may enable internal communication between two elements or an interaction relationship between two elements, unless otherwise explicitly defined. For those skilled in the art, the specific meaning of the above terms in this application may be understood according to specific circumstances.

In this application, unless otherwise explicitly specified and defined, a first feature “on” or “beneath” a second feature can mean that the first and second features are in direct contact, or that the first and second features are in indirect contact through an intermediate medium. Moreover, a first feature “above”, “over”, and “on top of” a second feature can mean that the first feature is directly above or obliquely above the second feature, or merely indicates that the horizontal height of the first feature is greater than that of the second feature. A first feature “below”, “under”, and “beneath” a second feature can mean that the first feature is directly below or obliquely below the second feature, or merely indicates that the horizontal height of the first feature is less than that of the second feature.

It should be noted that when an element is referred to as being “fixed to” or “disposed on” another element, it may be directly on the other element or there may be an intervening element. When an element is considered “connected” to another element, it may be directly connected to the other element or there may be an intervening element present. The terms “vertical”, “horizontal”, “upper”, “lower”, “left”, “right”, and similar expressions used herein are for illustrative purposes only and do not imply a unique embodiment.

In specific implementations of the related art, both ends of a copper cable may be directly connected to a chip package and an IO connector. However, due to the large dimensions of copper cables, problems of large occupied space and complex assembly processes exist, which are not suitable for scenarios requiring high density and massive interconnections.

Hereinafter, the chip-to-panel cable assembly 100 and the circuit board assembly 200 according to the embodiments of this application will be described with reference to the accompanying drawings.

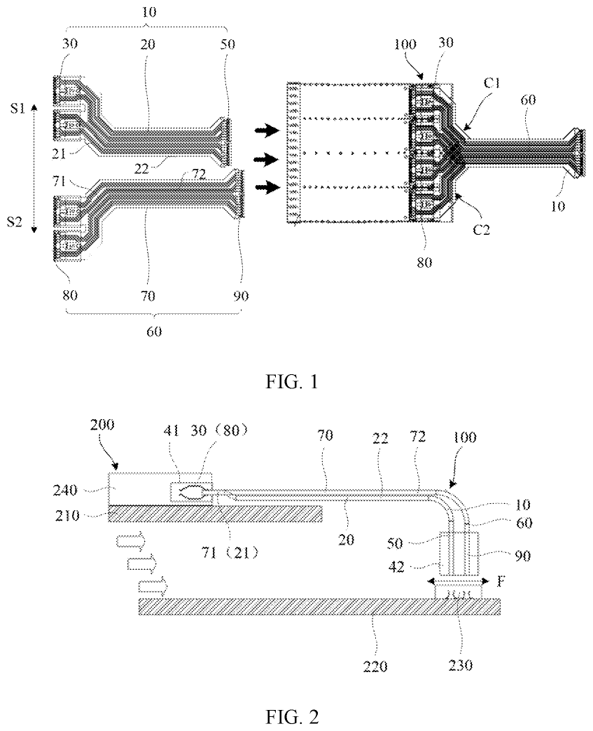

FIG. 1 is a schematic structural diagram of a chip-to-panel cable assembly according to an embodiment of this application, and FIG. 2 is a side view of a chip-to-panel cable assembly according to an embodiment of this application.

Referring to FIG. 1 and FIG. 2, the chip-to-panel cable assembly 100 (hereinafter referred to as cable assembly 100) according to an embodiment of this application includes at least a first connection unit 10 and a second connection unit 60. In FIG. 1, the process of assembling the first connection unit 10 and the second connection unit 60 into a cable assembly 100 is illustrated.

The first connection unit 10 includes a first flexible circuit board 20, and a first connector 30 and a second connector 50 that are disposed on the first flexible circuit board 20. The first connector 30 is used to be electrically connected to an external module, and the second connector 50 is used to be electrically connected to a chip connector 230 described hereinafter. The second connection unit 60 includes a second flexible circuit board 70, and a third connector 80 and a fourth connector 90 that are disposed on the second flexible circuit board 70. The third connector 80 is used to be electrically connected to the external module, and the fourth connector 90 is used to be electrically connected to the chip connector 230. At least a partial region of the first flexible circuit board 20 close to the second connector 50 and at least a partial region of the second flexible circuit board 70 close to the fourth connector 90 are stacked with each other.

The first connection unit 10 includes a first flexible circuit board 20, and a first connector 30 and a second connector 50 that are disposed on the first flexible circuit board 20. The first connector 30 is used to be electrically connected to an external module, and the second connector 50 is used to be electrically connected to the chip connector 230 described hereinafter, such that a partial electrical connection between the external module and the chip connector 230 is realized via the first connector 30, the first flexible circuit board 20, and the second connector 50. Furthermore, the second connection unit 60 includes a second flexible circuit board 70, and a third connector 80 and a fourth connector 90 that are disposed on the second flexible circuit board 70. The third connector 80 is used to be electrically connected to the external module, and the fourth connector 90 is used to be electrically connected to the chip connector 230, such that an electrical connection between the external module and the chip connector 230 is also realized via the third connector 80, the second flexible circuit board 70, and the fourth connector 90. Compared with copper cable connections in the related art, the occupied space is greatly reduced, and the structure can adapt to scenarios requiring high density and massive interconnections.

In this embodiment, at least a partial region of the first flexible circuit board 20 close to the second connector 50 and at least a partial region of the second flexible circuit board 70 close to the fourth connector 90 are stacked with each other. The first flexible circuit board 20 and the second flexible circuit board 70 are thin plate-like structures. Therefore, arranging at least a partial region of the first flexible circuit board 20 and at least a partial region of the second flexible circuit board 70 to be stacked with each other can greatly reduce the overall space occupied by the first flexible circuit board 20 and the second flexible circuit board 70, as compared with the side-by-side arrangement of the first flexible circuit board 20 and the second flexible circuit board 70. This structure releases heat dissipation space within the electronic device, thereby improving the heat dissipation performance of heating elements in the electronic device.

On the other hand, copper cable connection is no longer required, and relatively complex assembly processes are omitted accordingly. During connection, it is only necessary to perform plugging connection of the first connector 30 and the third connector 80 with a target external module, and perform plugging connection of the second connector 50 and the fourth connector 90 with a chip connector 230 on a target circuit board, which is relatively simple and easy to implement.

In this embodiment of this application, the cable assembly 100 including the first connection unit 10 and the second connection unit 60 is taken as an example for illustration. The quantity of connection units may be set as needed. The configuration for other quantities of connection units is similar, that is, the flexible circuit boards in each connection unit may be stacked one by one in sequence, which will not be repeated herein.

The first connector 30 and the third connector 80 may each be a high-density connector, for example, may each include at least one OSFP connector or OSFP-XD connector, where OSFP is a panel IO interface mode widely used in data communication.

An OSFP connector, also known as an octal small form-factor pluggable (OSFP) connector, is a pluggable package form developed by the OSFP multi-source agreement (MSA) organization.

An OSFP-XD connector, also known as an octal small form-factor pluggable eXtra dense (OSFP-XD) connector, is another pluggable package form, where a quantity of circuits is increased from 8 lanes to 16 lanes, and supports 16-lane 1.6 Tb/s density at 100 GB/s and 16-lane 3.2 Tb/s density at 200 GB/s.

The quantity of OSFP connectors (OSFP-XD connectors) included in the first connector 30 and the third connector 80 may be set according to actual needs, for example, it may be 1, 2, 3, or even more. In this embodiment of this application, it is illustrated by taking the first connector 30 and the third connector 80 both including two OSFP connectors as an example. The configuration of other quantities of OSFP connectors is similar, and will not be repeated herein.

Certainly, the first connector 30 and the third connector 80 may also adopt other types of connectors. The first connector 30 and the third connector 80 are used to be pluggably electrically connected to an external module. For example, if the first connector 30 and the third connector 80 are OSFP connectors, the external module may be an OSFP optical module.

The first flexible circuit board 20 and the second flexible circuit board 70 may be made of PETE material so as to reduce losses. PETE material, namely polytetrafluoroethylene, also known as Teflon, is a high molecular polymer obtained by polymerizing tetrafluoroethylene as a monomer. This material features acid resistance and alkali resistance, and resistance to various organic solvents, and is almost insoluble in all solvents.

In this embodiment of this application, the cable assembly 100 is applied to the circuit board assembly 200 to realize a physical channel from chip to panel. Referring to FIG. 2, the circuit board assembly 200 includes a first circuit board 210 (panel) and a second circuit board 220. The second circuit board 220 may be, for example, a main control circuit board. The second circuit board 220 is provided with a chip (not shown) and a chip connector 230 that are electrically connected to each other. The first connector 30 and the third connector 80 are disposed on the first circuit board 210. The second connector 50 and the fourth connector 90 may be in pluggable mating with the chip connector 230. The first connector 30 on the first circuit board 210 (panel) is electrically connected to the chip via the first flexible circuit board 20, the second connector 50, and the chip connector 230, so as to realize the physical channel from chip to panel. The third connector 80 on the first circuit board 210 (panel) is electrically connected to the chip via the second flexible circuit board 70, the fourth connector 90, and the chip connector 230, so as to realize the physical channel from chip to panel.

In this embodiment of this application, the second connector 50 and the fourth connector 90 may include, for example, gold fingers. This arrangement facilitates the pluggable connection of the second connector 50 and the fourth connector 90 with the chip connector 230 on the main control circuit board.

In this embodiment of this application, at least a partial region of the first flexible circuit board 20 close to the second connector 50 and at least a partial region of the second flexible circuit board 70 close to the fourth connector 90 are stacked with each other, meaning that when the cable assembly 100 is viewed from above (the perspective of FIG. 1 is a top view), the first flexible circuit board 20 and the second flexible circuit board 70 have an overlapping region, and the first flexible circuit board 20 and the second flexible circuit board 70 may completely overlap or partially overlap.

In some embodiments, referring to FIG. 1 and FIG. 2, the first flexible circuit board 20 includes a first portion 21 and a second portion 22 that are connected to each other and arranged at an angle. The first connector 30 is disposed on the first portion 21, and the second connector 50 is disposed on the second portion 22. Herein, the second portion 22 may be, for example, a strip extending substantially straight, and the first portion 21 may be arranged at a certain included angle relative to the second portion 22.

The second flexible circuit board 70 may include a third portion 71 and a fourth portion 72 that are connected to each other and arranged at an angle. The third connector 80 is disposed on the third portion 71, and the fourth connector 90 is disposed on the fourth portion 72. Herein, the fourth portion 72 may be, for example, a strip extending substantially straight, and the third portion 71 may be arranged at a certain included angle relative to the fourth portion 72.

The second portion 22 and the fourth portion 72 are stacked with each other to allow the second connector 50 and the fourth connector 90 to be stacked with each other. Combining FIG. 1 and FIG. 2, a gap is reserved between the first circuit board 210 and the second circuit board 220 to form a heat dissipation channel for cooling air (indicated by hollow arrows) to pass through. Since the second portion 22 and the fourth portion 72 are stacked with each other in the left-right direction of FIG. 2, and the second connector 50 and the fourth connector 90 are stacked with each other in the left-right direction of FIG. 2, the first connection unit 10 and the second connection unit 60 occupy a smaller space in the direction perpendicular to the plane of FIG. 2, and the windward area is reduced, and heat dissipation performance is thus optimized.

In this embodiment of this application, the first connector 30 and the third connector 80 are not stacked with each other. In other embodiments of this application, the first connector 30 and the third connector 80 may also be stacked with each other.

Referring to FIG. 1, in a possible embodiment, the first portion 21 includes a first diverging region C1, and the first connector 30 is disposed on the first diverging region C1. The second portion 22 includes a second diverging region C2, and the third connector 80 is disposed on the second diverging region C2. Projections of the first diverging region C1 and the second diverging region C2 on a first reference plane do not overlap, and the first reference plane is perpendicular to a stacking direction of the second portion 22 and the fourth portion 72 (the direction perpendicular to the plane in FIG. 1). In this way, the first connector 30 and the third connector 80 are spread out and not stacked.

In this embodiment of this application, the first portion 21 is bent towards a first side S1 of the cable assembly relative to the second portion 22, and the third portion 71 is bent towards a second side S2 of the cable assembly relative to the fourth portion 72. The first side S1 is opposite from and the second side S2 with respect to a second reference plane, and the second reference plane is perpendicular to the first reference plane. As shown in FIG. 1, the first portion 21 is bent upwards relative to the second portion 22, and the third portion 71 is bent downwards relative to the fourth portion 72.

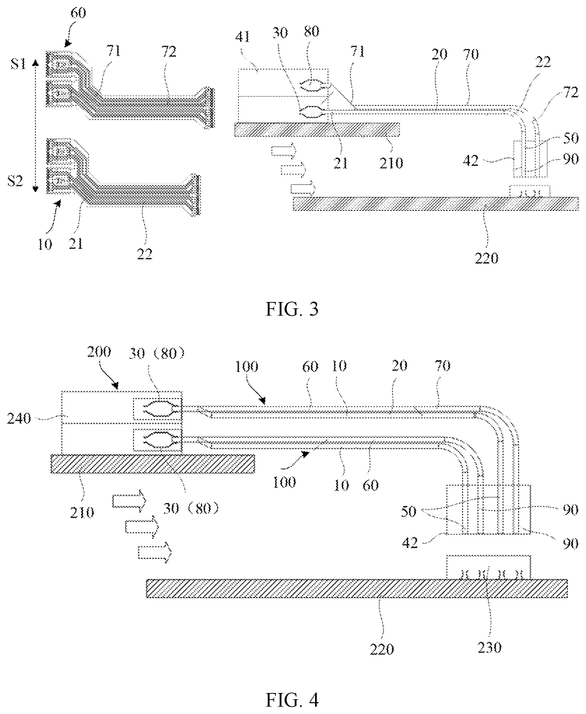

FIG. 3 is a schematic diagram of another structure of the chip-to-panel cable assembly according to an embodiment of this application. Unlike the case in which the first connector 30 and the third connector 80 are not stacked as shown in FIG. 1, referring to FIG. 3, the first portion 21 and the third portion 71 are stacked with each other to allow the first connector 30 and the third connector 80 to be stacked with each other. In this way, the space occupied by the first connector 30 and the third connector 80 on the first circuit board 210 can be reduced.

Further, in FIG. 3, the first portion 21 is bent towards a first side S1 of the cable assembly relative to the second portion 22, and the third portion 71 is also bent towards the first side S1 relative to the fourth portion 72.

It can be understood that, unless otherwise defined by the context, the stacked arrangement mentioned in this application refers to the relative positional relationship in the stacking direction, and the two stacked objects may be in contact with each other or not in contact with each other. In the example shown in FIG. 3, the first portion 21 and the third portion 71 are stacked with each other, but are partially out of contact with a gap reserved therebetween. The second portion 22 and the fourth portion 72 are stacked with each other, with partial contact and partial non-contact.

Further, combining FIG. 1 and FIG. 3, an area of the stacked portion of the second portion 22 and the fourth portion 72 is greater than 80% of an area of the second portion 22. Additionally or alternatively, an area of the stacked portion of the second portion 22 and the fourth portion 72 is greater than 80% of an area of the fourth portion 72.

This arrangement ensures that the second portion 22 and the fourth portion 72 have a sufficiently large stacked area, thereby minimizing the occupied space. Exemplarily, the projections of the second portion 22 and the fourth portion 72 on the first reference plane may completely overlap, such that the occupied space is minimized.

In this embodiment of this application, combining FIG. 2 and FIG. 3, the first connector 30 and the third connector 80 are fixed to optical cages 240 via first positioning members 41. In some embodiments, the second connector 50 and the fourth connector 90 are fixed with each other via the second positioning member 42. For example, the second connector 50 and the fourth connector 90 may be integrally formed with the second positioning member 42 through injection molding.

In the example of FIG. 1, a 1X4 OSFP cage is formed as the optical cage 240, meaning that one layer is provided in total and four OSFP connectors are arranged on each layer. In the example of FIG. 3, a 2X2 OSFP cage is formed as the optical cage 240, meaning that two layers are provided in total and two OSFP connectors are arranged on each layer. Certainly, this application is not limited thereto, and the structure and arrangement of the optical cage 240 may also be set according to actual needs.

Further, the first flexible circuit board 20 and the second flexible circuit board 70 are fixed with each other via a third positioning member (not shown). The third positioning member may be, for example, a clip or other fixing member. By providing mounting holes on the first flexible circuit board 20 and the second flexible circuit board 70, the first flexible circuit board 20 and the second flexible circuit board 70 may be fixed relative to each other by matching with fixing members such as clips and pins.

Through the arrangement of at least two of the first positioning member 41, the second positioning member 42, and the third positioning member, the first flexible circuit board 20 and the second flexible circuit board 70 can maintain a stacked state with each other.

Further, combining FIG. 2 and FIG. 3, the second connector 50 and the fourth connector 90 are fixed with each other via the second positioning member 42, and the second connector 50 and the fourth connector 90 have a spacing along a thickness direction of the second portion 22 and the fourth portion 72. The second portion 22 and the fourth portion 72 are configured as elongated strip-shaped members, and the second portion 22 and the fourth portion 72 are different in length.

This arrangement ensures that when the second portion 22 and the fourth portion 72 are stacked together, if the first flexible circuit board 20 and the second flexible circuit board 70 are bent, a gap may be reserved between the portion of the circuit board segment of the fourth portion 72 close to the fourth connector 90 and the portion of the circuit board segment of the second portion 22 close to the second connector 50.

In this embodiment of this application, referring to FIG. 3, an insertion direction of the second connector 50 and the fourth connector 90 relative to the chip connector 230 is perpendicular to an extension direction of the first flexible circuit board 20 in a horizontally orientated state. Alternatively, an insertion direction of the second connector 50 and the fourth connector 90 relative to the chip connector 230 may be along an extension direction of the first flexible circuit board 20 in a horizontally orientated state. The plugging manner depends on the arrangement direction of an insertion end of the chip connector 230.

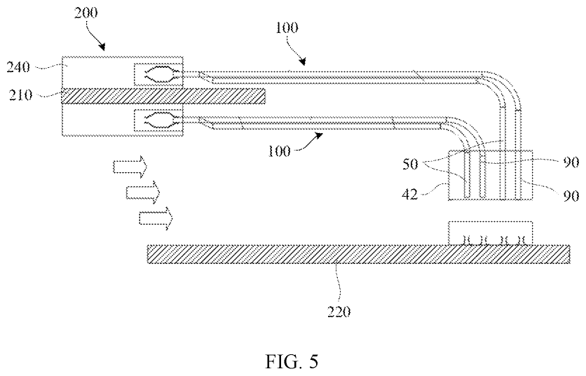

FIG. 4 is a schematic structural diagram of a circuit board assembly according to an embodiment of this application, and FIG. 5 is a schematic structural diagram of another structure of a circuit board assembly according to an embodiment of this application.

Referring to FIG. 4 and FIG. 5, embodiments of this application further provide a circuit board assembly 200, including a first circuit board 210, a second circuit board 220, an optical cage 240 that are arranged spaced apart from each other in a preset direction, and one or more cable assemblies 100 as described above.

The first connector 30 of the first connection unit 10 and the third connector 80 of the second connection unit 60 are disposed on the optical cage 240, and the optical cage 240 is disposed on the first circuit board 210. The second circuit board 220 is provided with a chip connector 230, and the second connector 50 and the fourth connector 90 are electrically connected to the chip connector 230. The preset direction herein may be, for example, the up-down direction during normal use of the electronic device.

A height difference exists between the first circuit board 210 and the second circuit board 220 in the preset direction, so that parts of the first flexible circuit board 20 and the second flexible circuit board 70 are bent, for example, bent by 90°, to facilitate connection.

Continuing to refer to FIG. 2, during heat dissipation, the cooling air, as indicated by the arrows, flows in through the gap between the first circuit board 210 and the second circuit board 220. Since the second portion 22 of the first flexible circuit board 20 and the fourth portion 72 of the second flexible circuit board 70 are stacked with each other, and the second portion 22 and the fourth portion 72 are partially twisted by 90° to form the vertical arrangement shown in FIG. 2, the cross-sectional area of the heat dissipation air duct can be further reduced, air duct resistance is lowered, and heat dissipation efficiency is improved accordingly.

Further, the quantity of the one or more cable assemblies 100 may be two, and the two cable assemblies 100 are stacked with each other along the thickness direction of the first circuit board 210. The second connector 50 and the fourth connector 90 of one of the cable assemblies 100 and the second connector 50 and the fourth connector 90 of the other one of the cable assemblies 100 are fixed with each other via the second positioning member 42. For example, the respective second connectors 50 and fourth connectors 90 in the two cable assemblies 100 may be integrally formed through injection molding.

In specific implementation, for example, as shown in FIG. 4, different cable assemblies 100 may be disposed on one side of the first circuit board 210, or as shown in FIG. 5, different cable assemblies 100 may be disposed on opposite sides of the first circuit board 210. Except that different positions of the first connector 30 of the cable assembly 100 leads to different spacing between the two cable assemblies 100, the arrangement and structure of other structural members in FIG. 5 are the same as those in FIG. 4, and will not be repeated herein.

In the specific connection process, the first connector 30 and the third connector 80 of the cable assembly 100 is first connected to the first circuit board 210, and then the second connector 50 and the fourth connector 90 is connected to the chip connector 230. In this way, the first flexible circuit board 20 and the second flexible circuit board 70 are partially bent by 90 degrees, and the connection can be realized.

In some other embodiments, based on the embodiment shown in FIG. 3, the chip connector 230 may also be so configured that an insertion direction is along the horizontal direction, that is, the second connector 50 and the fourth connector 90 are inserted into the chip connector 230 along the horizontal direction. In this case, neither the second portion 22 of the first flexible circuit board 20 nor the fourth portion 72 of the second flexible circuit board 70 is bent.

The technical features of the above-described embodiments can be arbitrarily combined. To make the description concise, not all possible combinations of the technical features in the above embodiments have been described. However, as long as these combinations of technical features do not contradict each other, they should be considered within the scope described in this specification.

The embodiments described above merely express several implementation methods of this application, and their description is relatively specific and detailed, but this should not be understood as limiting the scope of the patent application. It should be pointed out that for those skilled in the art, several modifications and improvements can be made without departing from the concept of this application, and these all fall within the protection scope of this application. Therefore, the protection scope of the patent of this application should be subject to the appended claims.

What is claimed is:

1. A chip-to-panel cable assembly, comprising:
a first connection unit (10) comprising:
a first flexible circuit board (20);
a first connector (30) disposed on the first flexible circuit board (20), the first connector (30) being used to be electrically connected to an external module; and
a second connector (50) disposed on the first flexible circuit board (20), the second connector (50) being used to be electrically connected to a chip connector (230); and
a second connection unit (60) comprising:
a second flexible circuit board (70);
a third connector (80) disposed on the second flexible circuit board (70), the third connector (80) being used to be electrically connected to the external module; and
a fourth connector (90) disposed on the second flexible circuit board (70), the fourth connector (90) being used to be electrically connected to the chip connector (230); wherein
at least a partial region of the first flexible circuit board (20) close to the second connector (50) and at least a partial region of the second flexible circuit board (70) close to the fourth connector (90) are stacked with each other.

2. The cable assembly according to claim 1, wherein the first flexible circuit board (20) comprises a first portion (21) and a second portion (22) that are connected to each other and arranged at an angle; wherein the first connector (30) is disposed on the first portion (21), and the second connector (50) is disposed on the second portion (22);
the second flexible circuit board (70) comprises a third portion (71) and a fourth portion (72) that are connected to each other and arranged at an angle; wherein the third connector (80) is disposed on the third portion (71), and the fourth connector (90) is disposed on the fourth portion (72); and
the second portion (22) and the fourth portion (72) are stacked with each other to allow the second connector (50) and the fourth connector (90) to be stacked with each other.

3. The cable assembly according to claim 2, wherein the first portion (21) comprises a first diverging region (C1), and the first connector (30) is disposed on the first diverging region (C1); and
the second portion (22) comprises a second diverging region (C2), and the third connector (80) is disposed on the second diverging region (C2); wherein
projections of the first diverging region (C1) and the second diverging region (C2) on a first reference plane do not overlap, and the first reference plane is perpendicular to a stacking direction of the second portion (22) and the fourth portion (72).

4. The cable assembly according to claim 3, wherein the first portion (21) is bent towards a first side (S1) of the cable assembly relative to the second portion (22), the third portion (71) is bent towards a second side (S2) of the cable assembly relative to the fourth portion (72), the first side (S1) is opposite from the second side (S2) with respect to a second reference plane, and the second reference plane is perpendicular to the first reference plane.

5. The cable assembly according to claim 2, wherein the first portion (21) is bent towards a first side (S1) of the cable assembly relative to the second portion (22), and the third portion (71) is also bent towards the first side (S1) relative to the fourth portion (72); and
the first portion (21) and the third portion (71) are stacked with each other to allow the first connector (30) and the third connector (80) to be stacked with each other.

6. The cable assembly according to claim 2, wherein an area of a stacked portion of the second portion (22) and the fourth portion (72) is greater than 80% of an area of the second portion (22) and/or greater than 80% of an area of the fourth portion (72).

7. The cable assembly according to claim 2, wherein the first connector (30) and the third connector (80) are fixed to an optical cage (240) via a first positioning member (41), respectively.

8. The cable assembly according to claim 2, wherein
the second connector (50) and the fourth connector (90) are fixed with each other via a second positioning member (42).

9. The cable assembly according to claim 2, wherein the first flexible circuit board (20) and the second flexible circuit board (70) are fixed with each other via a third positioning member.

10. The cable assembly according to claim 7, wherein the second connector (50) and the fourth connector (90) are fixed with each other via the second positioning member (42), and the second connector (50) and the fourth connector (90) have a spacing along a thickness direction of the second portion (22) and the fourth portion (72).

11. The cable assembly according to claim 10, wherein an insertion direction of the second connector (50) and the fourth connector (90) relative to the chip connector (230) is along an extension direction of the first flexible circuit board (20) in a horizontally orientated state.

12. The cable assembly according to claim 10, wherein an insertion direction of the second connector (50) and the fourth connector (90) relative to the chip connector (230) is perpendicular to an extension direction of the first flexible circuit board (20) in a horizontally orientated state.

13. The cable assembly according to claim 2, wherein the second portion (22) and the fourth portion (72) are elongated members, and the second portion (22) and the fourth portion (72) have different lengths.

14. A circuit board assembly (200), comprising: a first circuit board (210), a second circuit board (220), an optical cage (240) that are arranged spaced apart from each other in a preset direction, and one or more cable assemblies (100) according to claim 1, wherein
the first connector (30) of the first connection unit (10) and the third connector (80) of the second connection unit (60) are disposed on the optical cage (240), and the optical cage (240) is disposed on the first circuit board (210); and
the second circuit board (220) is provided with a chip connector (230), and the second connector (50) and the fourth connector (90) are connected to the chip connector (230).

15. The circuit board assembly (200) according to claim 10, wherein a quantity of the one or more cable assemblies (100) is two, and the two cable assemblies (100) are stacked with each other along a thickness direction of the first circuit board (210); wherein
the second connector (50) and the fourth connector (90) of one of the cable assemblies and the second connector (50) and the fourth connector (90) of the other one of the cable assemblies are fixed relative to each other by a second positioning member (42).
